(19) United States
(12) Patent Application Publication
(10) Pub. No.: US 2025/0034051 A1
(43) Pub. Date: Jan. 30, 2025

(54) COMPOSITE SUBSTRATE AND METHOD FOR MANUFACTURING SAME

(71) Applicant: NICHIA CORPORATION, Anan-shi (JP)

(72) Inventor: Atsushi HOSOKAWA, Tokushima-shi (JP)

(73) Assignee: NICHIA CORPORATION, Anan-shi (JP)

(21) Appl. No.: 18/765,311

(22) Filed: Jul. 7, 2024

(30) Foreign Application Priority Data
Jul. 27, 2023 (JP) 2023-122425

(51) Int. Cl. C04B 37/02

(52) U.S. Cl. CPC C04B 37/026; C04B 2237/124; C04B 2237/125; C04B 2237/36; C04B 2237/402; C04B 2237/407; C04B 2237/64; C04B 2237/66

(57) ABSTRACT

A composite substrate including a metal substrate having a first surface and a second surface opposite to the first surface, a ceramic substrate, and a bonding member disposed on the first surface. The bonding member bonds the metal substrate and the ceramic substrate. The ceramic substrate includes a plurality of sections and a groove between sections of the plurality of sections adjacent to each other. The bonding member is present in the groove.

### CROSS-REFERENCE TO RELATED APPLICATIONS

The present application claims priority under 35 U.S.C. § 119 to Japanese Patent Application No. 2023-122425, filed Jul. 27, 2023, the contents of which is hereby incorporated by reference in its entirety.

### BACKGROUND

### 1. Technical Field

The present disclosure relates to a composite substrate and a method for manufacturing the same.

### 2. Description of Related Art

To enhance heat dissipation of a ceramic substrate, a composite substrate obtained by bonding the ceramic substrate to a metal substrate is known. In a composite substrate having a large area, stress may be generated due to a difference in thermal expansion coefficient between the ceramic substrate and the metal substrate when both are bonded to each other, thereby causing the ceramic substrate to be warped or cracked. To suppress such stress, a method of providing a weak portion in a substrate in advance to induce cracking is known (for example, see Japanese Utility Model Publication No. S62-103266).

### SUMMARY

Embodiments of the present disclosure provide a composite substrate with reduced warpage and high heat dissipation and a method for manufacturing the same.

A first aspect of the present disclosure is a composite substrate including a metal substrate having a first surface and a second surface opposite to the first surface, a ceramic substrate, and a bonding member disposed on the first surface. The bonding member is configured to bond the metal substrate and the ceramic substrate. The ceramic substrate includes a plurality of sections and a groove between sections of the plurality of sections adjacent to each other. The bonding member is present in the groove.

A second aspect of the present disclosure is a method for manufacturing a composite substrate. The method includes providing a metal substrate having a first surface and a second surface opposite to the first surface, a ceramic substrate including a groove on a surface of the ceramic substrate, and a bonding material. The method includes disposing the bonding material on the first surface, disposing the ceramic substrate on the bonding material, and bonding the ceramic substrate and the metal substrate by heating the bonding material while pressing at least one of the ceramic substrate and the metal substrate toward the other to form a bonding member. In bonding the ceramic substrate and the metal substrate, the ceramic substrate is at least partially cracked along the groove to form a cracked groove, and the bonding member is disposed in the cracked groove.

One aspect of the present disclosure can provide a composite substrate with reduced warpage and high heat dissipation and a method for manufacturing the same.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1A is a schematic plan view illustrating a composite substrate according to a first embodiment.

FIG. 1B is a schematic cross-sectional view illustrating a cross section taken along line IB-IB in FIG. 1A.

FIG. 2A is a schematic cross-sectional view illustrating a provided metal substrate in a method for manufacturing the composite substrate according to the first embodiment.

FIG. 2B is a schematic cross-sectional view illustrating a state in which a bonding material is disposed on the metal substrate in the method for manufacturing the composite substrate according to the first embodiment.

FIG. 2C is a schematic cross-sectional view illustrating a state in which a ceramic substrate is disposed on the bonding material in the method for manufacturing the composite substrate according to the first embodiment.

FIG. 2D is a schematic cross-sectional view illustrating a state in which the ceramic substrate and the metal substrate are bonded to each other in the method for manufacturing the composite substrate according to the first embodiment.

FIG. 3A is a schematic cross-sectional view illustrating a state in which a ceramic substrate is disposed on a bonding material in a method for manufacturing a composite substrate according to a second embodiment.

FIG. 3B is a schematic cross-sectional view illustrating the composite substrate according to the second embodiment.

FIG. 4A is a schematic cross-sectional view illustrating a state in which a ceramic substrate is disposed on a bonding material in a method for manufacturing a composite substrate according to a third embodiment.

FIG. 4B is a schematic cross-sectional view illustrating the composite substrate according to the third embodiment.

### DETAILED DESCRIPTION

### Description of Embodiments

Embodiments according to the present disclosure are described below with reference to the drawings. However, the embodiments described below are merely intended to embody the technical concept according to the present disclosure, and the invention is not limited to the following description unless otherwise specified. The content described in one embodiment can also be applied to another embodiment or modification. The drawings schematically illustrate embodiments, and in order to clarify the description, scales, intervals, positional relationships, and the like of the members may be exaggerated, illustration of part of the members may be omitted, or an end view illustrating only a cut surface may be used as a cross-sectional view. Directions illustrated in the drawings indicate relative positions between constitution components and are not intended to indicate absolute positions. Members having the same names and reference characters, as a rule, represent the same members or members of the same quality, and detailed description thereof is omitted as appropriate.

### First Embodiment

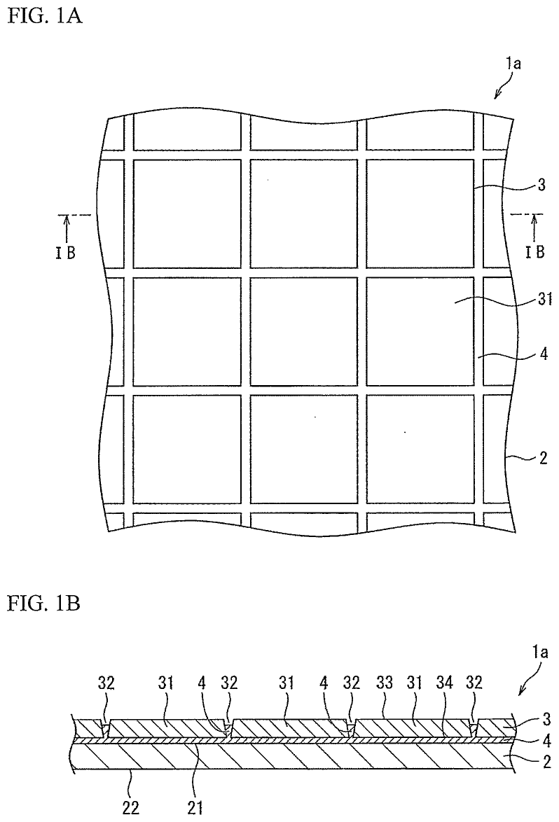

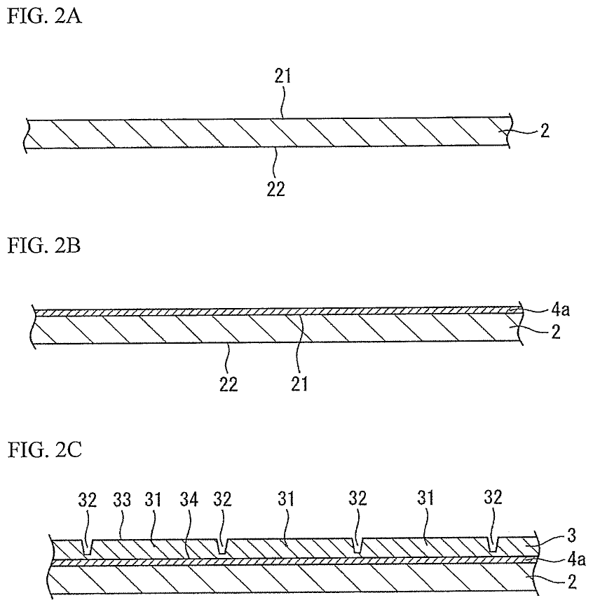

A composite substrate 1a and a method for manufacturing the composite substrate 1a according to a first embodiment are described with reference to FIGS. 1A, 1B and 2A to 2D. FIG. 1A is a schematic plan view illustrating the composite substrate 1a. FIG. 1B is a schematic cross-sectional view illustrating a cross section taken along line IB-IB in FIG. 1A. FIGS. 2A to 2D are schematic cross-sectional views for explaining the method for manufacturing the composite substrate 1a illustrated in FIGS. 1A and 1B.

The composite substrate 1a of the first embodiment according to the present disclosure includes a metal substrate 2 having a first surface 21 and a second surface 22 opposite to the first surface 21, a ceramic substrate 3, and a bonding member 4 disposed on the first surface 21 and configured to bond the metal substrate 2 and the ceramic substrate 3, the ceramic substrate 3 includes a plurality of sections 31 and a groove 32 between the sections 31 adjacent to each other, and the bonding member 4 is present in the groove 32.

The method for manufacturing the composite substrate 1a of the first embodiment according to the present disclosure includes (a) providing the metal substrate 2 having the first surface 21 and the second surface 22 opposite to the first surface 21, the ceramic substrate 3 including the groove 32, and the bonding material 4a, (b) disposing the bonding material 4a on the first surface 21, (c) disposing the ceramic substrate 3 on the bonding material 4a so that a surface opposite to a surface including the groove 32 faces the bonding material 4a, and (d) bonding the ceramic substrate 3 and the metal substrate 2 by heating the bonding material 4a while pressing at least one of the ceramic substrate 3 and the metal substrate 2 toward the other to form the bonding member 4. In bonding the ceramic substrate 3 and the metal substrate 2, the ceramic substrate 3 is at least partially cracked along the groove 32, and the bonding material 4a is disposed in the cracked groove 32 and heated to form the bonding member 4. The manufacturing process is described in detail below.

### (a) Providing Metal Substrate 2, Ceramic Substrate 3, and Bonding Material 4a

The metal substrate 2 having the first surface 21 and the second surface 22 opposite to the first surface 21, the ceramic substrate 3 including the grooves 32, and the bonding material 4a are provided (FIG. 2A). FIG. 2A does not illustrate the ceramic substrate 3 and the bonding material 4a.

In the composite substrate 1a, the metal substrate 2 supports the ceramic substrate 3. Since the metal substrate 2 has a higher thermal conductivity than the ceramic substrate 3, heat transmitted to the ceramic substrate 3 is transmitted to the metal substrate 2 and efficiently released to the outside.

The thickness of the metal substrate 2 is not particularly limited, but is preferably in a range from 200 μm to 2.0 mm, more preferably in a range from 300 μm to 1.5 mm. Setting the thickness of the metal substrate 2 to 200 μm or more allows the heat capacity of the metal substrate 2 to be increased, further improving the heat dissipation. Setting the thickness of the metal substrate 2 to 2.0 mm or less allows the thickness of the composite substrate 1a to be reduced, which is advantageous for miniaturization and height reduction.

The material of the metal substrate 2 is not particularly limited as long as the material has a high thermal conductivity. The material of the metal substrate 2 can contain at least one of Cu or Al. The metal substrate 2 can be substantially made of Cu or Al.

The ceramic substrate 3 is an insulating member serving as a base on which a wiring and the like are disposed later. The ceramic substrate 3 has a first surface 33 and a second surface 34 opposite to the first surface 33. The ceramic substrate 3 includes the grooves 32 on the first surface 33 side. The ceramic substrate 3 includes the plurality of sections 31 divided by the grooves 32. The grooves 32 are bottomed grooves. The grooves 32 are arranged in a lattice pattern on the first surface 33 side in plan view. That is, one of the sections 31 has a rectangular shape in plan view.

The thickness of the ceramic substrate 3 can be preferably in a range from 50 μm to 500 μm, for example, in a range from 100 μm to 400 μm or in a range from 150 μm to 300 μm.

The length of one side of one section 31 can be preferably 30 mm or less, more preferably 25 mm or less, for example, 20 mm or less. Setting the length of one side of one section 31 in the above range allows stress when the composite substrate 1a is formed, for example, stress due to a difference in thermal expansion coefficient between the metal substrate 2 and the ceramic substrate 3, to be relaxed and warpage of the composite substrate 1a to be suppressed. The length of one side of one section 31 can be preferably 3 mm or more, more preferably 5 mm or more. Setting the length of one side of one section 31 in the above range improves the degree of freedom in the arrangement of a wiring and the like to be disposed on the composite substrate 1a.

The depth of the groove 32 can be preferably in a range from one-fifth to four-fifths, more preferably in a range from two-fifths to three-fifths of the thickness of the ceramic substrate 3. Setting the depth of the groove 32 to one-fifth or more of the thickness of the ceramic substrate 3 causes the ceramic substrate 3 to be easily cracked along the grooves 32 when the ceramic substrate 3 is bonded to the metal substrate 2, allowing the individual sections 31 to be easily made independent and thus stress in the composite substrate 1a to be easily relaxed. Setting the depth of the groove 32 to four-fifths or less of the thickness of the ceramic substrate 3 ensures the strength of the ceramic substrate 3 and facilitates handling.

The depth of the groove 32 can be preferably in a range from 10 μm to 400 μm, for example, in a range from 20 μm to 300 μm, in a range from 30 μm to 240 μm, in a range from 40 μm to 240 μm, or in a range from 60 μm to 180 μm.

The grooves 32 can be formed, for example, by etching, blasting, or laser processing. Alternatively, a substrate formed with the grooves 32 can be purchased as the ceramic substrate 3.

The material of the ceramic substrate 3 is preferably ceramic having high thermal conductivity from the viewpoint of heat dissipation. Examples of the material of the ceramic substrate 3 include nitride-based ceramic such as silicon nitride, aluminum nitride, or boron nitride, and oxide-based ceramic such as aluminum oxide, silicon oxide, calcium oxide, or magnesium oxide. The ceramic substrate 3 is preferably nitride-based ceramic.

### (b) Disposing Bonding Material 4a

The bonding material 4a is disposed on the first surface 21 of the metal substrate 2 (FIG. 2B). The bonding material 4a is sintered by heating to become the bonding member 4 and bonds the ceramic substrate 3 and the metal substrate 2.

As the bonding material 4a, for example, a first metal paste including a metal powder, an active metal powder, and an organic binder can be used. As described below, the first metal paste can be fired at a temperature in a range from 780° C. to 1100° C.

As an example, the first metal paste preferably contains a metal powder in a range from 63 mass % to 85 mass %, an active metal powder in a range from 1 mass % to 15 mass %, and an organic binder serving as a solvent in a range from 5 mass % to 15 mass %, before sintering. The first metal paste serving as the bonding material 4a becomes a metal body serving as the bonding member 4, after firing. The surface of the metal powder can be covered with a coated metal member, and the coated metal member can be included in the metal body after firing. The active metal powder becomes a metal compound after firing. The first metal paste can contain an inorganic filler except for metal.

A median diameter of the metal powder is preferably in a range from 1 μm to 50 μm, more preferably in a range from 5 μm to 40 μm. When the median diameter of the metal powder is 1 μm or more, the metal powder is not easily aggregated and is easily handled. When the median diameter of the metal powder is 50 μm or less, the thickness of the bonding member can be reduced. The metal powder is preferably dispersed in the first metal paste together with an active metal powder, an organic binder, and optionally an inorganic filler. When the first metal paste contains a metal powder that does not melt even after firing, the metal powder can be dispersed in a metal body after firing. That is, when only a metal powder having a melting point equal to or less than the firing temperature or in the vicinity of the firing temperature is used as the metal powder, the entire metal powder becomes a metal body by firing, but when a metal powder having a melting point higher than the firing temperature is contained in the metal powder, part of the metal powder remains in the metal body. When a metal powder having a melting point equal to the firing temperature or lower than the firing temperature is heated above the melting point, the metal powder is melted and becomes a liquid, but when a metal powder having a melting point higher than the firing temperature is used, the metal powder itself does not become a liquid because it is heated at a temperature below the melting point of the metal powder. Since the metal powder does not become a liquid, the metal powder hardly flows to a large extent in the first metal paste. Moreover, containing an unmelted inorganic filler in the first metal paste allows the volume shrinkage of the first metal paste to be suppressed and the occurrence of warpage to be reduced. However, even at a firing temperature below the melting point of the metal powder, part of the surface of the metal powder can be in a softened state due to a reaction with a coated metal member, a particle diameter, a firing atmosphere, or the like, and the metal powder can be disposed in contact with or mixed with other metal powder. At this time, an interface can exist between the metal powder and the metal body, but no interface can exist therebetween. In this way, since no interface can exist between the metal powder and the metal body, an electric resistance value can be decreased, and electrical conductivity and thermal conductivity can be increased.

All or at least part of the metal powder preferably contains, for example, at least one selected from Ag, Al, Zn, Sn, and an Ag—Cu alloy. In particular, Ag and an Ag—Cu alloy are preferable. Since the melting point of Ag is about 962° C. and the melting point of the Ag—Cu alloy is about 780° C., firing can be performed at a relatively low temperature.

The metal powder can contain, for example, at least one selected from Cu, Cr, and Ni. The metal powder also includes an alloy containing Cu, Cr, and Ni as main components. The metal powder is particularly preferably Cu or a Cu alloy. This is because Cu, Cr, and Ni have high thermal conductivity. Cu, Cr, and Ni have high melting points, and when the firing temperature is below the melting points of these metals, these metals are not melted but are dispersed in the metal body, and thus have high thermal conductivity. At least one selected from Cu, Cr, and Ni can be coated with at least one coated metal member selected from Ag, Al, Zn, Sn, and an Ag—Cu alloy. That is, since the metal powder is coated with the coated metal member having a predetermined thickness, the metal powders do not come into contact with each other or are separated from each other more than necessary even after firing. In this way, since the metal powder is appropriately dispersed, uneven distribution of heat in a through hole can be suppressed.

At least a part or all of the active metal powder becomes a metal compound by firing. The metal compound can be disposed between the metal powders or can be disposed in the form of a layer at the interface with the ceramic substrate 3. The active metal powder is dispersed in the first metal paste, and the metal compound after firing is also dispersed in the metal body. For example, when titanium hydride (TiH₂) is used as the active metal powder, titanium hydride releases hydrogen by firing, and titanium is oxidized or nitrided into titanium oxide, titanium nitride, or the like. When the ceramic substrate 3 is a nitride-based ceramic, the active metal powder contained in the first metal paste reacts with nitrogen in the ceramic substrate to form a reaction layer of titanium nitride at the interface between the first metal paste and the ceramic substrate. When the ceramic substrate 3 is an oxide-based ceramic, the active metal powder contained in the first metal paste reacts with oxygen in the ceramic substrate to form a reaction layer of titanium oxide at the interface between the first metal paste and the ceramic substrate. The reaction product of the metal compound such as titanium nitride or titanium oxide is disposed so that spaces between the metal powders are continuous or disposed at the grain boundary. The metal compound is disposed directly contacting the metal powder, surrounding the metal powder, or surrounding the inorganic filler. The metal compound improves the adhesion strength to the ceramic substrate.

The active metal powder is preferably one or more materials selected from, for example, TiH₂, CeH₂, ZrH₂, LaH₂, and MgH₂. Firing the active metal powder causes all or part of hydrogen to be removed, react with nitrogen, oxygen, carbon, and the like contained in the ceramic substrate, the inorganic filler, and the like, and turn into a nitride metal, an oxide metal, a carbide metal, and the like. This resultant substance is a metal compound. TiH₂ is particularly preferably used as the active metal powder, and the active metal powder containing TiH₂ reacts with nitrogen contained in the ceramic substrate or the like to form a reaction layer such as TiN.

The inorganic filler is dispersed in the first metal paste to reduce the occurrence of cracking. The thickness of the ceramic substrate and the thickness of the metal substrate can be made constant by making the particle diameter of the inorganic filler uniform. Examples of the inorganic filler include a ceramic filler, a metal filler, and a glass filler. Specifically, aluminum oxide, silicon oxide, or the like can be used as the inorganic filler. The inorganic filler is contained in a content within a range that does not interfere with the effects of other inclusions.

The organic binder is a member contained in the first metal paste before firing. The organic binder is evaporated after firing and does not remain in the first metal paste. The organic binder can be, for example, a solvent and a resin material generally used as a via material.

In another example, the bonding material 4a can use a second metal paste containing an organic solvent having a boiling point in a range from 200° C. to 300° C. and a reducing property, at a proportion in a range from 5% to 20% of the weight of metal particles. As described below, the second metal paste can be fired at a temperature in a range from 150° C. to 300° C. When the boiling point of the second metal paste is in a temperature range in which the second metal paste is fired or in a temperature range slightly lower than the firing temperature, the organic solvent can be vaporized and removed when the second metal paste is fired. Since the organic solvent has a reducing property, oxidation of the metal particles can be suppressed, and sintering can be promoted. However, the boiling point of the organic solvent contained in the second metal paste can be in a temperature range slightly lower than the firing temperature. This is because the organic solvent can be vaporized even in a temperature range lower than the firing temperature. This is due to factors such as the thickness and the size of the second metal paste and how heat is applied to the second metal paste during firing. The boiling point of the organic solvent contained in the second metal paste being in a temperature range slightly lower than the firing temperature means that the boiling point of the organic solvent can be in a temperature range lower than the firing temperature and in which a difference from the firing temperature is 80° C. or less or 50° C. or less, for example.

The second metal paste used as the bonding material 4a contains a metal powder, for example, at least one of Ag or Cu. Using the second metal paste as the bonding material 4a allows the heating temperature for bonding the ceramic substrate 3 and the metal substrate 2 to be set to a relatively low temperature, allowing a load on the ceramic substrate 3 and the metal substrate 2 to be reduced. For example, stress due to a difference in thermal expansion coefficient between the ceramic substrate 3 and the metal substrate 2 can be reduced, and thus the warpage of the composite substrate 1a can be reduced.

The median diameter of the above metal powder is preferably in a range from 0.1 μm to 20 μm, more preferably in a range from 0.5 μm to 10 μm, further preferably a range from 1 μm to 5 μm. When the median diameter of the metal powder is 0.1 μm or more, aggregation can be suppressed. On the other hand, when the median diameter of the metal powder is 20 μm or less, the filling property can be improved. The shape of the metal powder is preferably spherical or ellipsoidal from the viewpoint of fluidity but can be flat or needle-like. This is because the contact between particles can be increased or thermal conductivity can be increased by making the metal powder flat or needle-like.

The second metal paste used as the bonding material 4a can further contain an organic resin binder. The viscosity of the bonding material 4a can be adjusted depending on the type and amount of the organic resin binder. As the organic resin binder, for example, a solvent generally used for a metal paste, or a resin material such as acrylic, epoxy, urethane, ethyl cellulose, silicone, phenol, polyimide, polyurethane, melamine, or urea can be used. The organic resin binder can be decomposed by heating to be described below, evaporated, and removed.

The method of disposing the bonding material 4a is not particularly limited. For example, when the bonding material 4a is the first metal paste or the second metal paste, the first metal paste or the second metal paste can be applied and disposed to be in close contact with the first surface 21 of the metal substrate 2. The bonding material 4a disposed on the first surface 21 of the metal substrate 2 becomes the bonding member 4 in a subsequent heating step.

The thickness of the layer of the bonding material 4a on the first surface 21 of the metal substrate 2 is preferably in a range from 5 μm to 250 μm, more preferably in a range from 10 μm to 200 μm, and further preferably in a range from 20 μm to 100 μm.

### (c) Disposing Ceramic Substrate 3

The ceramic substrate 3 is disposed on the bonding material 4a so that the surface opposite to the surface formed with the grooves 32 faces the bonding material 4a (FIG. 2C). The method of disposing the ceramic substrate 3 is not particularly limited.

### (d) Bonding Ceramic Substrate 3 and Metal Substrate 2.

The bonding member 4 is formed by heating the bonding material 4a while pressing at least one of the ceramic substrate 3 and the metal substrate 2 toward the other, and the ceramic substrate 3 and the metal substrate 2 are bonded to each other (FIG. 2D). Thus, the composite substrate 1a according to the first embodiment is obtained.

The ceramic substrate 3 and the metal substrate 2 can be bonded to each other by, for example, pressing the ceramic substrate 3 toward the metal substrate 2 or pressing the metal substrate 2 toward the ceramic substrate 3. Thus, the ceramic substrate 3 is cracked along the grooves 32. Although the ceramic substrate 3 is cracked along all the grooves 32 in the first embodiment, the present disclosure is not limited thereto, and the ceramic substrate 3 is at least partially cracked. For example, in the ceramic substrate 3, 30% or more of the groove 32 is preferably cracked, 50% or more thereof is preferably cracked, 70% or more thereof is further preferably cracked, 90% or more thereof is still further preferably cracked, 95% or more thereof is particularly preferably cracked. The ceramic substrate 3 is cracked along the grooves 32, causing the ceramic substrate 3 to be divided into the sections 31. The ceramic substrate 3 being divided into the sections 31 allows stress due to a difference in thermal expansion coefficient between the ceramic substrate 3 and the metal substrate 2 to be reduced and thus the warpage of the composite substrate 1a to be reduced. The ceramic substrate 3 is cracked along the grooves 32, causing the bonding material 4a to enter the grooves 32. The division of the ceramic substrate 3 needs not be caused only by the above pressing but can be caused by thermal expansion by the following heating.

The magnitude of the pressurization is preferably in a range from 0.01 MPa to 10 MPa, more preferably in a range from 0.05 MPa to 5 MPa. The above pressing with the pressure in the above range allows the ceramic substrate 3 to be easily cracked along the grooves 32.

The above pressing method is not particularly limited, but a method that can press the entire ceramic substrate 3 or metal substrate 2 is preferable. Examples of the pressing method include a method of pressing the entire ceramic substrate 3 or metal substrate 2 by using a plate, and a method of pressing the ceramic substrate 3 or the metal substrate 2 by applying a roller in one direction or two orthogonal directions. The entire pressing allows the ceramic substrate 3 to be easily cracked across the entire groove 32. In the pressing, the ceramic substrate 3 or the metal substrate 2 is preferably pressed with a cushioning material interposed. The cushioning material is preferably disposed between the ceramic substrate 3 and a pressing device, for example, a plate. The pressing with the cushioning material interposed allows the ceramic substrate 3 to be suppressed from being cracked in an unintended portion, that is, a portion other than the groove 32.

The heating temperature in the above heating is appropriately selected depending on the bonding material 4a to be used. For example, when the bonding material 4a is the second metal paste, the heating temperature is, for example, in a range from 150° C. to 300° C., preferably in a range from 180° C. to 280° C. When the bonding material 4a is the first metal paste, the heating temperature is, for example, in a range from 780° C. to 1100° C., preferably in a range from 800° C. to 1050° C. The bonding material 4a becomes the bonding member 4 by heating. For example, when the bonding material 4a is the first metal paste, the bonding material 4a is sintered to form the bonding member 4. The metal substrate 2 and the ceramic substrate 3 are bonded to each other by the bonding member 4.

As described above, in bonding the ceramic substrate 3 and the metal substrate 2 to each other, the ceramic substrate 3 is at least partially cracked along the grooves 32. Subsequently, the bonding material 4a enters the cracked grooves 32 and is heated to form the bonding member 4. In this way, the ceramic substrate 3 is cracked along the grooves 32, resulting in the ceramic substrate 3 divided into the sections 31 by the grooves 32. The bonding member 4 is disposed in the grooves 32.

Since the ceramic substrate 3 is divided into the sections 31, the influence of stress due to a difference in thermal expansion coefficient between the ceramic substrate 3 and the metal substrate 2 is reduced, and the warpage of the composite substrate 1a is reduced. The amount of the warpage of the composite substrate 1a is preferably 300 μm or less, more preferably 200 μm or less, further preferably 100 μm or less. The amount of the warpage means a maximum distance in a thickness direction (for example, a stacking direction) from a straight line connecting both ends of an upper surface of the composite substrate 1a (the first surface 33 of the ceramic substrate 3 in the first embodiment) to the upper surface located between both the ends. The amount of the warpage can be measured by, for example, a laser microscope or a contact-type step measuring device. For example, VR-5200 manufactured by Keyence Corporation can be used. Alternatively, a contact-type step measuring device (Alpha-Step D-500 manufactured by KLA-Tenchore Co., Ltd) can be used.

In the composite substrate 1a, disposing the bonding member 4 in the groove 32 allows a contact area between the ceramic substrate 3 and the bonding member 4 to be increased, the thermal conductivity between the ceramic substrate 3 and the bonding member 4 to be improved, and the heat dissipation effect to be improved.

In the composite substrate 1a, since the bonding material is heated while at least one of the ceramic substrate 3 and the metal substrate 2 is pressed toward the other, air contained in the bonding material 4a or gas generated by heating is pushed out to the outside, reducing a porosity in the obtained bonding member 4. In particular, since the ceramic substrate 3 is cracked at the groove 32 in this step, the groove 32 also serves as a discharge portion for the above gas, allowing the porosity in the bonding member 4 to be further reduced.

The porosity in the bonding member 4 under the sections 31 of the ceramic substrate 3 is preferably 1% or less, more preferably 0.5% or less. Reducing the porosity in the bonding member 4 allows the thermal conductivity of the bonding member 4 to be improved and the heat dissipation effect of the composite substrate 1a to be improved.

The thickness of the bonding member 4 is preferably in a range from 5 μm to 200 μM, more preferably in a range from 5 μm to 200 μm. Increasing the thickness of the bonding member 4 improves the bonding property of the bonding member 4. Reducing the thickness of the bonding member 4 allows for more efficient heat conduction from the ceramic substrate 3 to the metal substrate 2. That is, setting the thickness of the bonding member 4 in the above range can achieve both the bonding property and the thermal conductivity.

A standard deviation of the thickness of the bonding member 4 between the plurality of sections 31 of the ceramic substrate 3 is preferably 10 μm or less, more preferably 5 μm or less. Setting the standard deviation of the thickness of the bonding member 4 in the above range also allows variations in the thickness of the composite substrate 1a to be reduced and the reliability to be improved.

The bonding member 4 in the grooves 32 of the ceramic substrate 3 is present to fill preferably 20% or more, more preferably 50% or more, further preferably 70% or more, still more preferably 80% or more, particularly preferably 90% or more of the thickness of the ceramic substrate 3 but can be present to fill 100% thereof. Setting the filling amount of the bonding member 4 in the groove 32 within the above range allows the contact area between the bonding member 4 and the ceramic substrate 3 to be increased and the heat dissipation effect of the composite substrate 1a to be improved. The bonding member 4 having 100% of the thickness of the ceramic substrate 3 means that the bonding member 4 completely fills both cracked grooves and initially formed grooves and that the surfaces of the bonding member 4 and the ceramic substrate 3 are flush with each other. When the surfaces of the bonding member 4 and the ceramic substrate 3 are flush with each other, a flat plate-like member is preferably pressed to come into contact with the surface of the ceramic substrate 3. Alternatively, after the metal substrate 2 and the ceramic substrate 3 are bonded to each other, the surface of the ceramic substrate 3 is preferably polished or ground.

The porosity, thickness, and standard deviation of the thickness of the bonding member 4 can be obtained by cutting the composite substrate 1a in the thickness direction and observing the cross-section with a scanning electron microscope (SEM) or the like. The cutting position is typically a position passing through the center of the section 31 in plan view. For example, when the section 31 has a rectangular shape, the section 31 is cut at positions where respective midpoints of two opposing sides are connected, in plan view. The porosity can be calculated by calculating the proportion of void portions in the bonding member 4 under the section 31. Alternatively, the void ratio can also be calculated from an area of a void occurrence site observed by X-ray observation or ultrasonic microscope observation from the substrate surface layer. For example, the void ratio can be measured by an X-ray CT method. The thickness is a thickness of the thickest portion under the section 31 in the above cross section. The standard deviation of the thickness can be calculated by measuring the thickness under each section 31 observed in the above cross section and calculating the standard deviation of the measured thickness.

### Second Embodiment

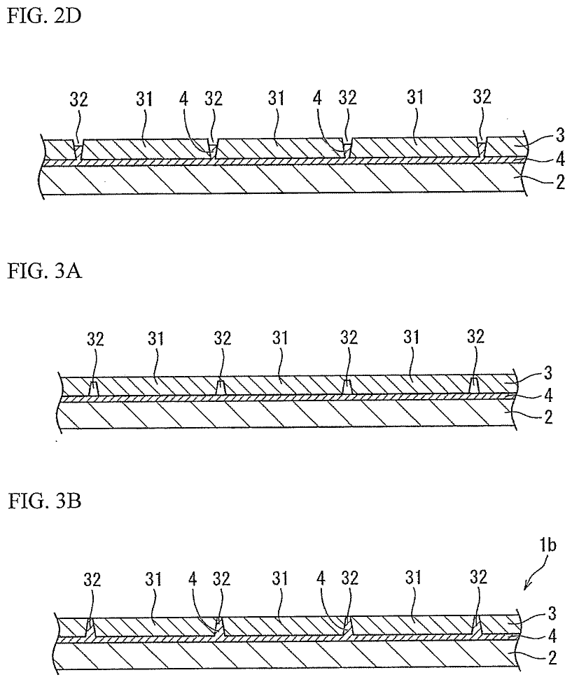

A composite substrate 1b and a method for manufacturing the same according to a second embodiment are described with reference to FIGS. 3A and 3B. FIG. 3A corresponds to FIG. 2C according to the first embodiment. FIG. 3B is a schematic cross-sectional view illustrating a cross section of the composite substrate 1b according to the second embodiment.

The method for manufacturing the composite substrate 1b is different from the method for manufacturing the composite substrate 1a according to the first embodiment in that in (c) disposing the ceramic substrate 3 on the bonding material 4a, the ceramic substrate 3 is disposed on the bonding material 4a so that the surface formed with the grooves 32 faces the bonding material 4a. That is, in the method for manufacturing the composite substrate 1b, the second surface 34 of the ceramic substrate 3 is disposed to face the bonding material 4a.

In the method for manufacturing the composite substrate 1b according to the second embodiment, since the composite substrate 1a is manufactured by disposing the ceramic substrate 3 on the bonding material 4a so that the surface formed with the grooves 32 faces the bonding material 4a, the bonding material 4a easily enters the grooves 32 and the bonding member 4 is easily disposed in the grooves 32. Since the second surface 34 of the ceramic substrate 3, which has no grooves 32, serves as the surface of the composite substrate 1b, the unevenness on the surface of the ceramic substrate 3 can be reduced or eliminated.

In the composite substrate 1b, the bonding member 4 in the grooves 32 of the ceramic substrate 3 is present in an amount of preferably 90% or more, more preferably 95% or more, further preferably 100% of the thickness of the ceramic substrate 3. When the bonding member 4 occupies 100% of the thickness of the ceramic substrate 3, it means that cracked grooves are completely filled with the bonding member 4 and the surfaces of the bonding member 4 and the ceramic substrate 3 are flush with each other. When the surfaces of the bonding member 4 and the ceramic substrate 3 are flush with each other, a flat plate-like member is preferably pressed to come into contact with the surface of the ceramic substrate 3. Alternatively, after the metal substrate 2 and the ceramic substrate 3 are bonded to each other, the surface of the ceramic substrate 3 is preferably polished or ground.

### Third Embodiment

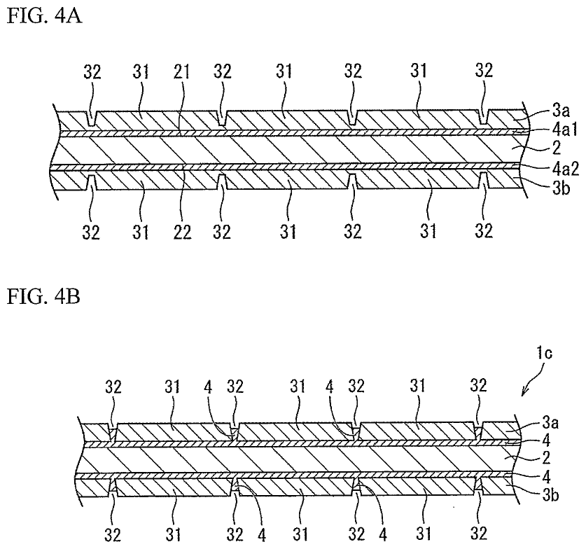

A composite substrate 1c and a method for manufacturing the same according to a third embodiment are described with reference to FIGS. 4A and 4B. FIG. 4A corresponds to FIG. 2C according to the first embodiment. FIG. 4B is a schematic cross-sectional view illustrating a cross section of the composite substrate 1c according to the third embodiment.

The composite substrate 1c according to the third embodiment is different from the composite substrate 1a according to the first embodiment in that a ceramic substrate 3a and another ceramic substrate 3b are provided on both the first surface 21 and the second surface 22 of the metal substrate 2, respectively.

The method for manufacturing the composite substrate 1c is different from the composite substrate 1a according to the first embodiment in that (b) disposing the bonding material 4a includes disposing a bonding material 4al on the first surface 21 of the metal substrate 2 and disposing a bonding material 4a2 on the second surface 22 and (c) disposing the ceramic substrate includes disposing the ceramic substrate 3a on the bonding material 4al and disposing the ceramic substrate 3b on the bonding material 4a2.

In the illustrated example, the ceramic substrates 3a and 3b are disposed so that the surface opposite to the surface formed with the grooves 32 faces the bonding material 4al or 4a2; however, the ceramic substrates 3a and 3b can be disposed so that the surface formed with the grooves 32 faces the bonding material 4al or 4a2 like the second embodiment.

1. A composite substrate, comprising:
a metal substrate having a first surface and a second surface opposite to the first surface;
a ceramic substrate; and
a bonding member disposed on the first surface, the bonding member being configured to bond the metal substrate and the ceramic substrate,
wherein the ceramic substrate comprises a plurality of sections and a groove between sections of the plurality of sections adjacent to each other, and
the bonding member is present in the groove.

2. The composite substrate according to claim 1, wherein the groove is arranged in a lattice pattern in plan view.

3. The composite substrate according to claim 2, wherein the plurality of sections of the ceramic substrate each have a rectangular shape with one side of 30 mm or less in plan view.

4. The composite substrate according to claim 1, wherein a thickness of the ceramic substrate is in a range from 50 μm to 500 μm.

5. The composite substrate according to claim 1, wherein a thickness of the metal substrate is in a range from 200 μm to 2.0 mm.

6. The composite substrate according to claim 1, wherein a thickness of the bonding member is in a range from 5 μm to 200 μm.

7. The composite substrate according to claim 1, wherein a standard deviation of a thickness of the bonding member between the plurality of sections of the ceramic substrate is 5 μm or less.

8. The composite substrate according to claim 1, wherein a porosity in the bonding member under the plurality of sections of the ceramic substrate is 1% or less.

9. The composite substrate according to claim 1, wherein an amount of warpage is 300 μm or less.

10. The composite substrate according to claim 1, wherein the ceramic substrate is a nitride-based ceramic substrate.

11. The composite substrate according to claim 1, wherein the metal substrate contains at least one of Cu or Al.

12. The composite substrate according to claim 1, wherein the bonding member contains at least one of Ag or Cu.

13. The composite substrate according to claim 1, wherein another bonding member and another ceramic substrate are further disposed on the second surface of the metal substrate.

14. A method for manufacturing a composite substrate, the method comprising:
providing a metal substrate having a first surface and a second surface opposite to the first surface, a ceramic substrate comprising a groove on a surface of the ceramic substrate, and a bonding material;
disposing the bonding material on the first surface;
disposing the ceramic substrate on the bonding material; and
bonding the ceramic substrate and the metal substrate by heating the bonding material while pressing at least one of the ceramic substrate and the metal substrate toward the other to form a bonding member,
wherein, in the bonding of the ceramic substrate and the metal substrate, the ceramic substrate is at least partially cracked along the groove to form a cracked groove, and
wherein the bonding member is disposed in the cracked groove.

15. The method for manufacturing a composite substrate according to claim 14, wherein, in the bonding of the ceramic substrate and the metal substrate, a temperature of the heating is in a range from 780° C. to 1100° C.

16. The method for manufacturing a composite substrate according to claim 14, wherein, in the bonding of the ceramic substrate and the metal substrate, a temperature of the heating is in a range from 150° C. to 300° C.

17. The method for manufacturing a composite substrate according to claim 14, wherein, in the bonding of the ceramic substrate and the metal substrate, a magnitude of the pressing is in a range from 0.1 MPa to 10 MPa.

18. The method for manufacturing a composite substrate according to claim 14, wherein, in the bonding of the ceramic substrate and the metal substrate, the ceramic substrate and the metal substrate are pressed with a pressing device with a cushioning material interposed between the ceramic substrate and the pressing device.

19. The method for manufacturing a composite substrate according to claim 14,
wherein a thickness of the ceramic substrate is in a range from 50 μm to 500 μm, and
wherein a depth of the groove is in a range from one-fifth to four-fifths of a thickness of the ceramic substrate.
